(19) United States
(12) Patent Application Publication
(10) Pub. No.: US 2026/0082930 A1
(43) Pub. Date: Mar. 19, 2026

(54) SEMICONDUCTOR INTEGRATED CIRCUIT AND RECEIVING DEVICE

(71) Applicant: Kioxia Corporation, Tokyo (JP)

(72) Inventor: Hayato TAKITA, Kamakura (JP)

(73) Assignee: Kioxia Corporation, Tokyo (JP)

(21) Appl. No.: 19/072,323

(22) Filed: Mar. 6, 2025

(30) Foreign Application Priority Data
Sep. 18, 2024 (JP) 2024-161057

(51) Int. Cl. H01L 23/66; H10D 1/20

(52) U.S. Cl. CPC H10W 44/20; H10D 1/20; H10W 44/234

(57) ABSTRACT

According to one embodiment, a semiconductor integrated circuit having a first inductive element and a second inductive element is provided. The first inductive element is provided in a first signal line. The second inductive element is provided in a loop arranged apart from the first signal line. The second inductive element is magnetically coupled to the first inductive element. The first signal line has signal terminals arranged at both ends. The loop is configured to be devoid of a signal terminal.

### CROSS-REFERENCE TO RELATED APPLICATIONS

This application is based upon and claims the benefit of Japanese Patent Application No. 2024-161057, filed on Sep. 18, 2024; the entire contents of which are incorporated herein by reference.

### FIELD

Embodiments described herein relate generally to a semiconductor integrated circuit and a receiving device.

### BACKGROUND

A receiving device with a semiconductor integrated circuit receives a signal through the semiconductor integrated circuit. Given that, in the semiconductor integrated circuit, a channel along which a signal is transferred has a characteristic impedance, it is desirable to appropriately match the impedance in the semiconductor integrated circuit.

### BRIEF DESCRIPTION OF THE DRAWINGS

FIG. 1 is a block diagram illustrating a configuration of a receiving device including a semiconductor integrated circuit according to an embodiment is applied;

FIG. 2 is a circuit diagram illustrating a configuration of the semiconductor integrated circuit according to an embodiment;

FIG. 3 is a circuit diagram illustrating a configuration of a matching circuit in an embodiment;

FIGS. 4A and 4B are circuit diagrams illustrating configurations of a matching circuit and a load in an embodiment and a comparative example;

FIG. 5 is a diagram illustrating frequency characteristics of an input resistance in an embodiment and the comparative example;

FIG. 6 is a diagram illustrating frequency characteristics of an input reactance in an embodiment and the comparative example;

FIG. 7 is a diagram illustrating frequency characteristics of an S11 parameter in an embodiment and the comparative example;

FIG. 8 is a plan view illustrating a configuration of a matching circuit in a first modification of an embodiment;

FIG. 9 is a circuit diagram illustrating a configuration of a semiconductor integrated circuit according to a second modification of an embodiment;

FIG. 10 is a circuit diagram illustrating a configuration of a matching circuit in the second modification of an embodiment;

FIG. 11 is a plan view illustrating a configuration of a matching circuit in a third modification of an embodiment;

FIGS. 12A and 12B are a plan view and a cross-sectional view illustrating a configuration of a matching circuit in a fourth modification of an embodiment;

FIGS. 13A and 13B are a plan view and a cross-sectional view illustrating a configuration of a matching circuit in a fifth modification of an embodiment;

FIGS. 14A and 14B are a plan view and a cross-sectional view illustrating a configuration of a matching circuit in a sixth modification of an embodiment;

FIGS. 15A and 15B are a plan view and a cross-sectional view illustrating a configuration of a matching circuit in a seventh modification of an embodiment;

FIGS. 16A and 16B are a plan view and a cross-sectional view illustrating a configuration of a matching circuit in an eighth modification of an embodiment;

FIG. 17 is a perspective view illustrating a configuration of a matching circuit in an eighth modification of an embodiment;

FIGS. 18A and 18B are a plan view and a cross-sectional view illustrating a configuration of a matching circuit in a ninth modification of an embodiment; and

FIG. 19 is a perspective view illustrating a configuration of a matching circuit in the ninth modification of an embodiment.

### DETAILED DESCRIPTION

In general, according to one embodiment, there is provided a semiconductor integrated circuit including a first inductive element, and a second inductive element. The first inductive element is provided in a first signal line. The second inductive element is provided in a loop and magnetically coupled to the first inductive element. The loop is arranged apart from the first signal line. The first signal line has signal terminals arranged at both ends. The loop is configured to be devoid of the signal terminal.

Exemplary embodiments of a semiconductor integrated circuit will be explained below in detail with reference to the accompanying drawings. The present invention is not limited to the following embodiments.

### Embodiments

A semiconductor integrated circuit according to an embodiment has a characteristic impedance, and technics are taken to appropriately match the impedance.

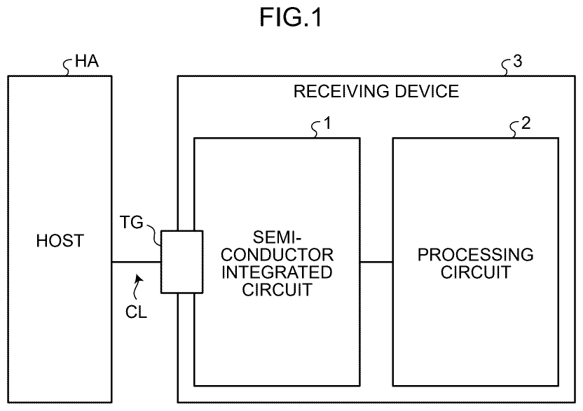

A semiconductor integrated circuit 1 can be applied to a receiving device 3 as illustrated in FIG. 1. FIG. 1 is a block diagram illustrating a configuration of the receiving device 3 to which the semiconductor integrated circuit 1 is applied.

The receiving device 3 is connectable to a host HA. The receiving device 3 includes the semiconductor integrated circuit 1 and a processing circuit 2. The semiconductor integrated circuit 1 includes a terminal group TG. The semiconductor integrated circuit 1 may be connectable to a communication line CL via the terminal group TG. The semiconductor integrated circuit 1 is capable of receiving information from the host HA by being connected to the host HA via the communication line CL. The host HA is an example of a transmitting device.

The semiconductor integrated circuit 1 is connected to the processing circuit 2 via an internal wiring. The semiconductor integrated circuit 1 is capable of transferring information received from the host HA to the processing circuit 2. The processing circuit 2 is capable of performing particular reception processing on the transferred information.

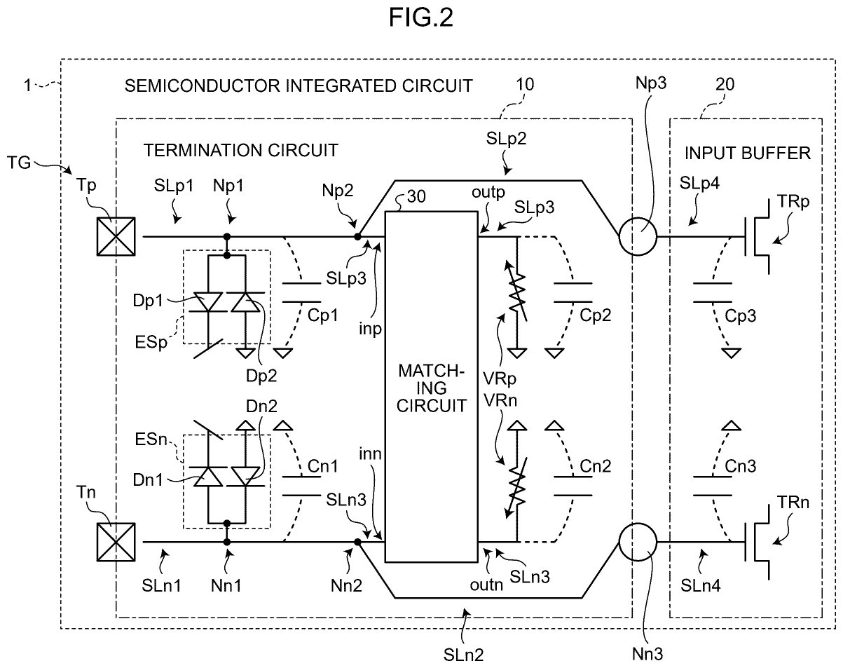

The semiconductor integrated circuit 1 can be configured as illustrated in FIG. 2. FIG. 2 is a circuit diagram illustrating a configuration of the semiconductor integrated circuit 1.

The semiconductor integrated circuit 1 may have a differential configuration. A signal received by the semiconductor integrated circuit 1 may be differential.

The semiconductor integrated circuit 1 includes a termination circuit 10 and an input buffer 20. In a case where the semiconductor integrated circuit 1 has a differential configuration, the termination circuit 10 and the input buffer 20 each have a P-side configuration and an N-side configuration.

The termination circuit 10 has terminals Tp and Tn, which receive a differential signal and transfer the received differential signal to the input buffer 20. The terminals Tp and Tn are included in the terminal group TG (refer to FIG. 1).

The termination circuit 10 further includes ESD protection circuits ESp and ESn, variable resistive elements VRp and VRn, and a matching circuit 30.

The terminal Tp receives a P-side signal of the differential signal from the host HA via the communication line CL. The terminal Tn receives an N-side signal of the differential signal from the host HA via the communication line CL.

The terminal Tp and a node Np2 are connected by a P-side signal line SLp1. The ESD protection circuit ESp is connected to a node Np1, which is between the terminal Tp and the node Np2 on the signal line SLp1. The ESD protection circuit ESp includes a diode Dp1 and a diode Dp2. The diode Dp1 has a cathode connected to a power supply line to which a power supply potential is applied, and an anode connected to the node Np1. The diode Dp2 has a cathode connected to the node Np1, and an anode connected to a ground line to which a ground potential is applied. The power supply potential is the potential of a power supply voltage for the semiconductor integrated circuit 1 to operate. The ground potential is the potential of a reference voltage for the semiconductor integrated circuit 1 to operate.

The ESD protection circuit ESp has a parasitic capacitance Cp1. The parasitic capacitance Cp1 is equivalent to a capacitor with a first end connected to the node Np1 and a second end connected to the ground line.

The terminal Tn and a node Nn2 are connected by an N-side signal line SLn1. The ESD protection circuit ESn is connected to a node Nn1, which is between the terminal Tn and the node Nn2 on the signal line SLn1. The ESD protection circuit ESn includes a diode Dn1 and a diode Dn2. The diode Dn1 has a cathode connected to the power supply line and an anode connected to the node Nn1. The diode Dn2 has a cathode connected to the node Nn1 and an anode connected to the ground line.

The ESD protection circuit ESn has a parasitic capacitance Cn1. The parasitic capacitance Cn1 is equivalent to a capacitor with a first end connected to the node Nn1 and a second end connected to the ground line.

A signal line SLp2 and a signal line SLp3 are connected to the node Np2. The signal line SLp2 connects the node Np2 and a node Np3. The signal line SLp3 electrically connects the node Np2 and the variable resistive element VRp via the matching circuit 30.

The variable resistive element VRp has a first end connected to the signal line SLp3 and a second end connected to the ground line.

The variable resistive element VRp has a parasitic capacitance Cp2. The parasitic capacitance Cp2 is equivalent to a capacitor with a first end connected to the signal line SLp3 and a second end connected to the ground line.

A signal line SLn2 and a signal line SLn3 are connected to the node Nn2. The signal line SLn2 connects the node Nn2 and a node Nn3. The signal line SLn3 electrically connects the node Nn2 and the variable resistive element VRn via the matching circuit 30.

The variable resistive element VRn has a first end connected to the signal line SLn3 and a second end connected to the ground line.

The variable resistive element VRn has a parasitic capacitance Cn2. The parasitic capacitance Cn2 is equivalent to a capacitor with a first end connected to the signal line SLn3 and a second end connected to the ground line.

The matching circuit 30 is provided or inserted between the node Np2 and the variable resistive element VRp on the signal line SLp3, and between the node Nn2 and the variable resistive element VRn on the signal line SLn3.

The matching circuit 30 includes input nodes inp and inn and output nodes outp and outn.

The input node inp is arranged between the node Np2 and the output node outp on the signal line SLp3. The output node outp is arranged between the input node inp and the variable resistive element VRp on the signal line SLp3.

The input node inn is arranged between the node Nn2 and the output node outn on the signal line SLn3. The output node outn is arranged between the input node inn and the variable resistive element VRn on the signal line SLn3.

The input buffer 20 transfers the differential signal that is transferred from the termination circuit 10 to the processing circuit 2 (refer to FIG. 1). The input buffer 20 includes input transistors TRp and TRn.

The input transistor TRp has a gate connected to the node Np3 via a signal line SLp4. The input transistor TRp has a drain or a source connected to the processing circuit 2.

The input transistor TRp has a parasitic capacitance Cp3. The parasitic capacitance Cp3 is equivalent to a capacitor with a first end connected to the signal line SLp4 and a second end connected to the ground line.

The input transistor TRn has a gate connected to the node Nn3 via a signal line SLn4. The input transistor TRn has a drain or a source connected to the processing circuit 2.

The input transistor TRn has a parasitic capacitance Cn3. The parasitic capacitance Cn3 is equivalent to a capacitor with a first end connected to the signal line SLn4 and a second end connected to the ground line.

The semiconductor integrated circuit 1 has a characteristic impedance. The matching circuit 30 is configured to perform impedance matching for the semiconductor integrated circuit 1.

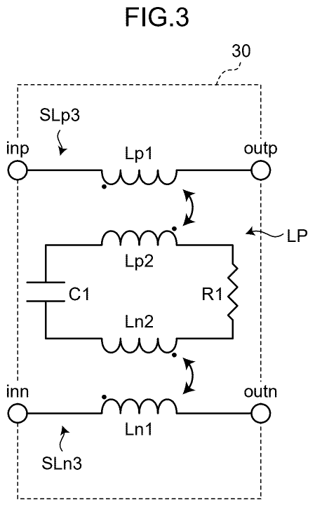

The matching circuit 30 can be configured as illustrated in FIG. 3. FIG. 3 is a circuit diagram illustrating a configuration of the matching circuit 30.

The matching circuit 30 includes an inductive element Lp1 and an inductive element Ln1.

The inductive element Lp1 is provided or inserted between the input node inp and the output node outp on the signal line SLp3. The inductive element Lp1 may be a coil. The inductive element Lp1 has a first end connected to the node Np2 via the input node inp, and a second end connected to the variable resistive element VRp via the output node outp (refer to FIG. 2).

The inductive element Ln1 is provided or inserted between the input node inn and the output node outn on the signal line SLn3. The inductive element In1 may be a coil. The inductive element Ln1 has a first end connected to the node Nn2 via the input node inn, and a second end connected to the variable resistive element VRn via the output node outn (refer to FIG. 2).

A configuration in which the inductive element Lp1 and the variable resistive element VRp are connected via the signal line SLp3 to the node Np2 to which the signal line SLp1 and the input transistor TRp are connected via the signal line SLp2, the node Np3, and the signal line SLp4 constitutes a P-side bridged-T coil topology.

The variable resistive element VRp has a resistance value adjusted to suppress signal reflections.

The inductive element Lp1 has an inductance value that can be experimentally determined in advance as an appropriate value for reducing the influence of noise caused by the parasitic capacitances Cp1 and Cp3 over a relatively wide frequency band. The inductance value of the inductive element Lp1 may be 140 pH.

The P-side bridged-T coil topology is capable of concealing the parasitic capacitance Cp1 of the ESD protection circuit ESp and the parasitic capacitance Cp3 of the input transistor TRp.

Similarly, a configuration in which the inductive element Ln1 and the variable resistive element VRn are connected via the signal line SLn3 to the node Nn2 to which the signal line SLn1 and the input transistor TRn are connected via the signal line SLn2, the node Nn3, and the signal line SLn4 constitutes an N-side bridged-T coil topology.

The variable resistive element VRn has a resistance value adjusted to suppress signal reflections.

The inductive element 1n1 has an inductance value that can be experimentally determined in advance as an appropriate value for reducing the influence of noise caused by the parasitic capacitances Cn1 and Cn3 over a relatively wide frequency band. The inductance value of the inductive element Ln1 may be 140 pH.

The N-side bridged-T coil topology is capable of concealing the parasitic capacitance Cn1 of the ESD protection circuit ESn and the parasitic capacitance Cn3 of the input transistor TRn.

However, it is difficult to conceal the parasitic capacitance Cp2 of the variable resistive element VRp using the P-side bridged-T coil topology, and it is difficult to conceal the parasitic capacitance Cn2 of the variable resistive element VRn using the N-side bridged-T coil topology.

In contrast, the matching circuit 30 further includes an inductive element Lp2, an inductive element Ln2, a resistive element R1, and a capacitive element C1.

The inductive element Lp2, the inductive element Ln2, the resistive element R1, and the capacitive element C1 are provided or inserted in a loop LP. The loop LP is arranged spaced apart from both the signal line SLp3 and the signal line SLn3. The signal line SLp3 and the signal line SLn3 extend parallel to each other. The loop LP is arranged between the signal line SLp3 and the signal line SLn3. The inductive element Lp2 may be provided or inserted in a portion, along the signal line SLp3, of the loop LP. The inductive element Ln2 may be provided or inserted in a portion, along the signal line SLn3, of the loop LP.

The inductive element Lp2 is magnetically coupled to the inductive element Lp1, as indicated by the solid arrow. The coupling coefficient between the inductive element Lp1 and the inductive element Lp2 can be preset to any optional value appropriate for concealing the parasitic capacitance Cp2. The coupling coefficient may be, for example, 0.6.

The inductance value of the inductive element Lp2 can be experimentally determined in advance as a value appropriate for reducing the influence of noise caused by the parasitic capacitance Cp2 over a relatively wide frequency band. The inductance value of the inductive element Lp2 may be 150 pH.

The inductive element Ln2 is magnetically coupled to the inductive element Ln1 as indicated by the solid arrow. The coupling coefficient between the inductive element Ln1 and the inductive element Ln2 can be preset to any optional value appropriate for concealing the parasitic capacitance Cn2. The coupling coefficient may be, for example, 0.6.

The inductance value of the inductive element Ln2 can be experimentally determined in advance as a value appropriate for reducing the influence of noise caused by the parasitic capacitance Cn2 over a relatively wide frequency band. The inductance value of the inductive element Ln2 may be 150 pH.

The resistive element R1 is inserted in the loop LP in such a way as to be connected in series with the inductive element Lp2 and the inductive element Ln2. The resistance value of the resistive element R1 can be experimentally determined in advance depending on the values of the parasitic capacitances Cp2 and Cn2 to be concealed. The resistance value of the resistive element R1 may be 40Ω.

The capacitive element C1 is inserted in the loop LP in such a way as to be connected in series with the inductive element Lp2 and the inductive element Ln2. The capacitance value of the capacitive element C1 can be experimentally determined in advance depending on the values of the parasitic capacitances Cp2 and Cn2 to be concealed. The capacitance value of the capacitive element C1 may be 160 fF.

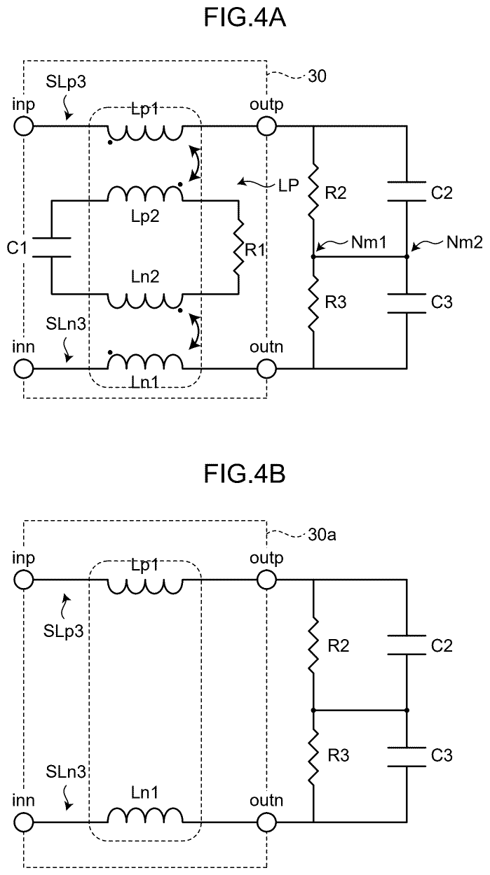

In the configuration illustrated in FIG. 2, a load connected to the matching circuit 30 is equivalently configured as illustrated in FIG. 4A, in which two resistors R2 and R3 and two capacitors C2 and C3 are bridge-connected. FIGS. 4A and 4B are circuit diagrams illustrating the configurations of matching circuits and loads in the embodiment and a comparative example. FIG. 4A is a circuit diagram illustrating the configuration of the matching circuit and the load in the embodiment, and FIG. 4B is a circuit diagram illustrating the configuration of a matching circuit and a load in the comparative example. The matching circuit 30 and the load in the embodiment are now described.

The resistors R2 and R3 are connected in series between the output node outp on the P-side and the output node outn on the N-side of the matching circuit 30.

The resistor R2 corresponds to the adjusted resistance value of the variable resistive element VRp and may have a resistance value of, for example, 39Ω.

The resistor R3 corresponds to the adjusted resistance value of the variable resistive element VRn and may have a resistance value of, for example, 39Ω.

The capacitors C2 and C3 are connected in parallel with the series-connected resistors R2 and R3, and connected in series between the output node outp on the P-side and the output node outn on the N-side of the matching circuit 30.

The capacitor C2 has a capacitance value corresponding to the capacitance value of the parasitic capacitance Cp2 and may be, for example, 100 fF.

The capacitor C3 has a capacitance value corresponding to the capacitance value of the parasitic capacitance Cn2 and may be, for example, 100 fF.

An intermediate node Nm1 between the resistors R2 and R3 and an intermediate node Nm2 between the capacitors C2 and C3 are connected to each other.

The intermediate nodes Nm1 and Nm2 each correspond to the ground line.

The matching circuit 30 illustrated in FIG. 4A diverts a portion of the energy of the signal transmitted through the inductive elements Lp1 and Ln1 to the inductive elements Lp2 and Ln2, which are magnetically coupled to the inductive elements Lp1 and Ln1, respectively, and the diverted energy is dissipated in the resistive element R1 and the capacitive element C1.

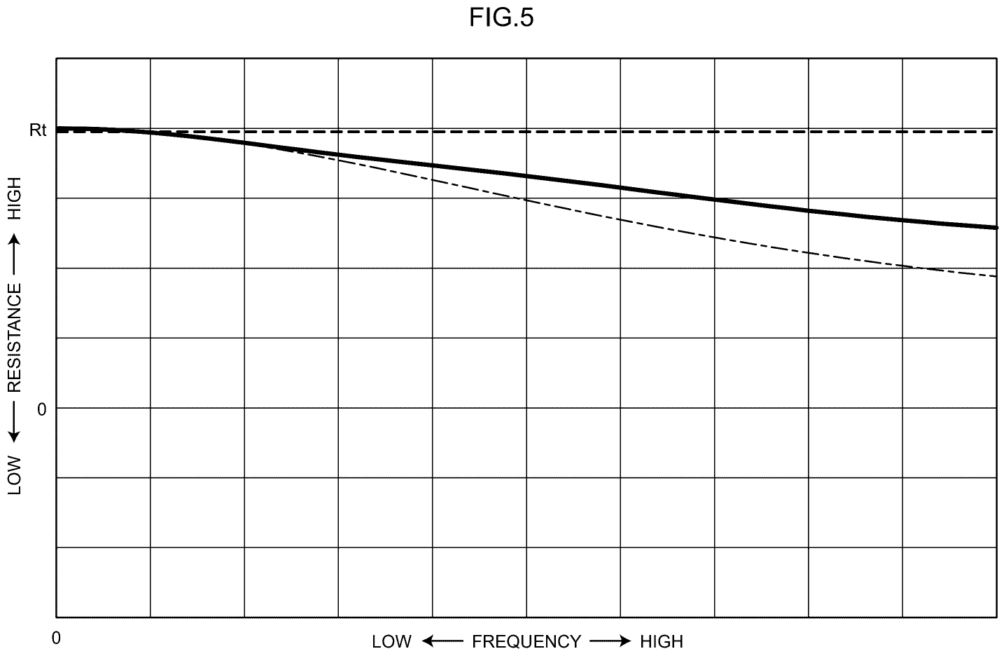

This configuration enables the matching circuit 30 to maintain the input resistance close to a desired resistance value Rt (e.g., 40Ω) over a wide frequency range from low to high frequency regions, as indicated by the solid line in FIG. 5. FIG. 5 is a diagram illustrating the frequency characteristics of the input resistance. In FIG. 5, the vertical axis represents the resistance value, and the horizontal axis represents the frequency.

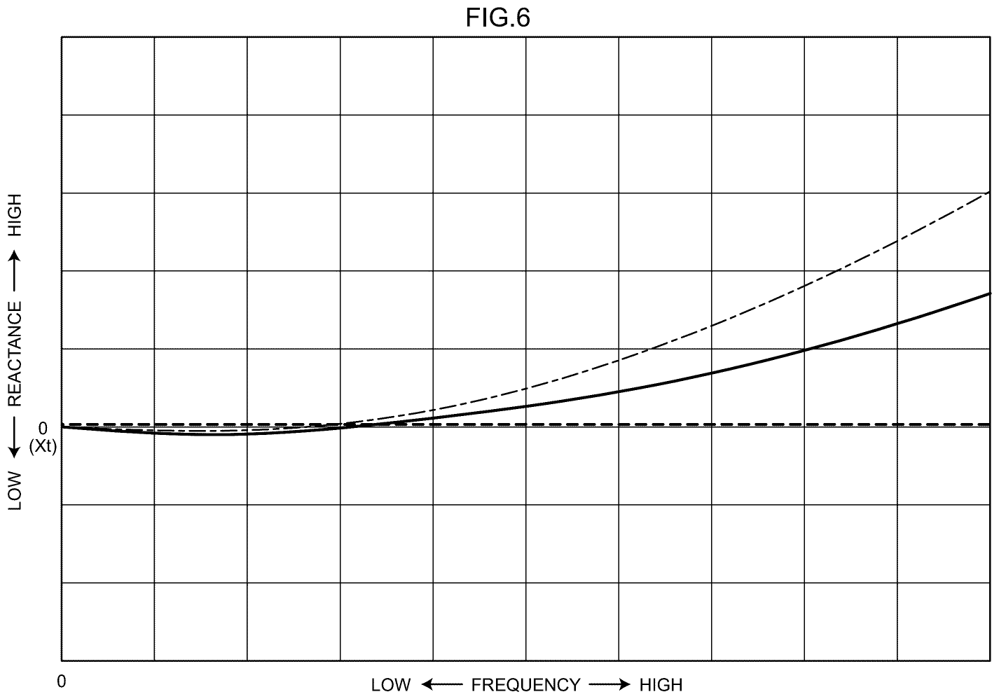

The matching circuit 30 is capable of maintaining the input reactance close to a desired reactance value Xt (e.g., 0Ω) over a wide frequency range from low to high frequency regions, as indicated by the solid line in FIG. 6. FIG. 6 is a diagram illustrating the frequency characteristics of the input reactance. In FIG. 6, the vertical axis represents the reactance value, and the horizontal axis represents the frequency.

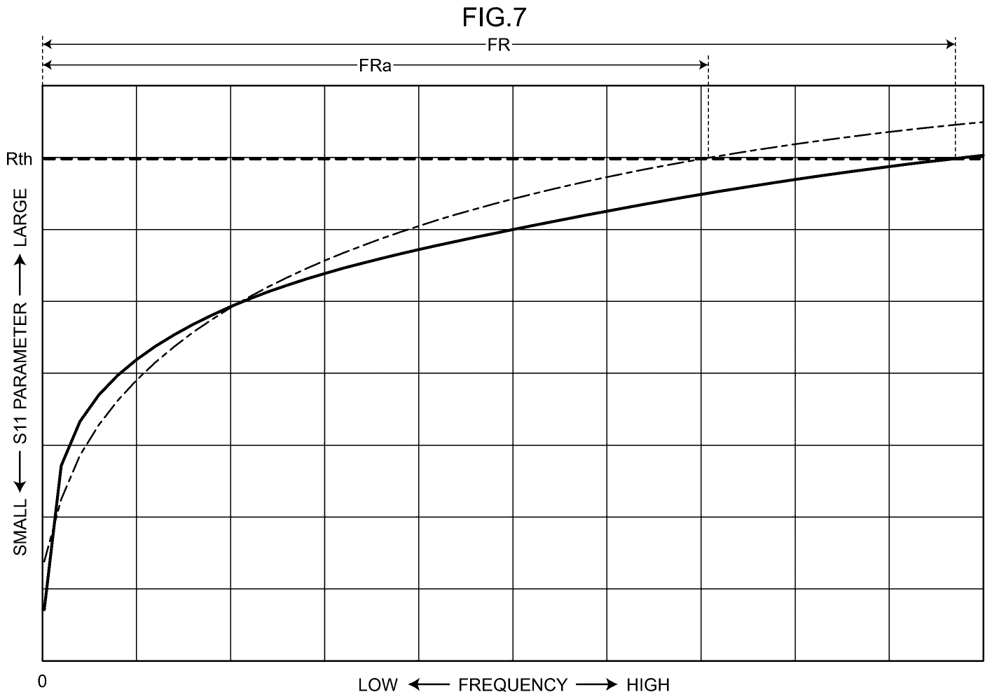

The matching circuit 30 is capable of maintaining the input resistance close to the desired resistance value Rt and the input reactance close to the desired reactance value Xt over a wide frequency range, so this enables the reflection characteristics of the signal to be kept within an allowable range over a wide frequency range FR, as indicated by the solid line in FIG. 7. For example, the value of an S11 parameter of the signal is capable of being maintained less than or equal to a threshold value Rth (e.g., −10 dB) over the wide frequency range FR.

FIG. 7 is a diagram illustrating the frequency characteristics of the S11 parameter. In FIG. 7, the vertical axis represents the S11 parameter value, and the horizontal axis represents the frequency. The S11 parameter is a parameter that represents the signal reflection, and although it uses the input impedance instead of the characteristic impedance of the line, it can approximately represent the degree of impedance matching of the line.

As described above, in the embodiment, in the matching circuit 30 of the semiconductor integrated circuit 1, the inductive element Lp2 magnetically coupled to the inductive element Lp1 of the signal line SLp3 and the inductive element Ln2 magnetically coupled to the inductive element Ln1 of the signal line SLn3 are provided on the loop LP spaced apart from the signal lines SLp3 and SLn3, respectively. The resistive element R1 and the capacitive element C1 are further provided on the loop LP. This enables the matching circuit 30 to divert a portion of the energy of the signal transmitted through the signal lines Lp1 and Ln1 from the inductive elements Lp1 and Ln1 to the inductive elements Lp2 and Ln2 magnetically coupled to the inductive elements Lp1 and Ln1, respectively, and the diverted energy may be dissipated in the resistive element R1 and the capacitive element C1. As a result, the reflection characteristics of the signal can be kept within the allowable range over the wide frequency range FR (refer to FIG. 7), which makes it possible for the parasitic capacitance Cp2 of the variable resistive element VRp to be concealed and for the parasitic capacitance Cn2 of the variable resistive element VRn to be concealed. Thus, it is possible to properly match the impedance in the semiconductor integrated circuit 1.

In the comparative example, a matching circuit 30a and a load are now described. For example, as illustrated in FIG. 4B, the matching circuit 30a is modified by omitting the loop LP.

In this case, the matching circuit 30a delivers most of the energy of the signal transmitted through the inductive elements Lp1 and Ln1 to a load (a configuration in which two resistors R2 and R3 and two capacitors C2 and C3 are bridge-connected).

As a result, compared to the characteristics of the matching circuit 30 indicated by the solid line in FIG. 5, the matching circuit 30a has an input resistance that tends to decrease and deviate from the desired resistance value Rt (e.g., 40Ω) as the frequency increases from the low-frequency region to the high-frequency region, as indicated by the dashed line in FIG. 5.

Compared to the characteristics of the matching circuit 30 indicated by the solid line in FIG. 6, the matching circuit 30a has an input reactance value that tends to increase and deviate from the desired reactance value Xt (e.g., 0Ω) as the frequency increases from the low-frequency region to the high-frequency region, as indicated by the dashed line in FIG. 6.

Compared to the characteristics of the matching circuit 30 indicated by the solid line in FIG. 7, the matching circuit 30a has the input resistance value decreases and deviates from the desired resistance value Rt as the frequency increases, and the input reactance value increases and deviates from the desired reactance value Xt as the frequency increases, so that a frequency range FRa in which the reflection characteristics of the signal are capable of being kept within the allowable range is likely to be relatively narrower, as indicated by the dashed line in FIG. 7. For example, the frequency range FRa in which the S11 parameter value of the signal can be maintained less than or equal to the threshold value Rth (e.g., −10 dB) is relatively narrower.

On the other hand, the matching circuit 30 is capable of maintaining the input resistance value close to the desired resistance value Rt over the wide frequency range, and maintaining the input reactance value close to the desired reactance value Xt over the wide frequency range, so that the reflection characteristics of the signal can be kept within the allowable range over the relatively wide frequency range FR (>FRa), as indicated by the solid line in FIG. 7. For example, the S11 parameter value of the signal is capable of being maintained less than or equal to the threshold value Rth (e.g., −10 dB) over the relatively wide frequency range FR.

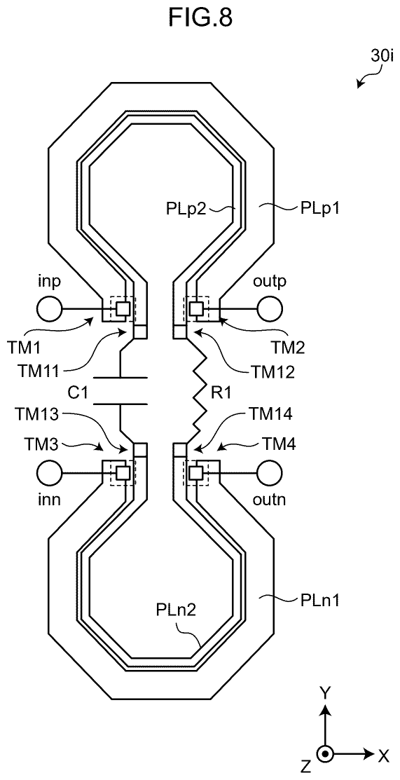

Moreover, as a first modification of the embodiment, a matching circuit 30i may be implemented as illustrated in FIG. 8. FIG. 8 is a plan view illustrating a configuration of the matching circuit 30i according to the first modification of the embodiment. The matching circuit 30i illustrated in FIG. 8 corresponds to the matching circuit 30 (refer to FIG. 3) and is implemented in a differential configuration.

The inductive element Lp1, the inductive element Lp2, the inductive element Ln1, and the inductive element Ln2 (refer to FIG. 3) may be implemented as a planar coil PLp1, a planar coil PLp2, a planar coil PLn1, and a planar coil PLn2 illustrated in FIG. 8, respectively.

The planar coil PLp1, the planar coil PLp2, the planar coil PLn1, and the planar coil PLn2 may be arranged on substantially the same plane. In the following description, the direction perpendicular to a plane on which the planar coil PLp1, the planar coil PLp2, the planar coil PLn1, and the planar coil PLn2 are arranged is referred to as the Z direction, and two directions perpendicular to each other in a plane perpendicular to the Z direction are referred to as the X direction and the Y direction.

The planar coil PLp1 and the planar coil PLp2 may each has a concentric pattern in the XY plane. The planar coil PLp1 is spaced outward from the planar coil PLp2 in the XY plane. The spacing in each of the X and Y directions can be determined experimentally in advance depending on a coupling coefficient to be achieved between the planar coil PLp1 and the planar coil PLp2.

As viewed in the XY plane, the planar coil PLp1 forms an annular-like shape, extending from a terminal TM1 on the −X side and −Y side and reaching a terminal TM2 on the +X side and −Y side. As viewed in the XY plane, the planar coil PLp2 forms an annular-like shape, extending from a terminal TM11 on the −X side and −Y side and reaching a terminal TM12 on the +X side and −Y side inside the planar coil PLp1. The terminals TM1 and TM2 may be located outward from the terminals TM11 and TM12, respectively, as viewed in the XY plane. In FIG. 8, the patterns of the planar coils PLp1 and PLp2 are illustrated as having an approximately octagonal shape, but they may be approximately tetragonal to heptagonal, approximately polygon with nine or more corners, or even approximately circular.

In the planar coil PLp1, the terminal TM1 is electrically connected to an input node inp of the matching circuit 30i, and the terminal TM2 is electrically connected to an output node outp of the matching circuit 30i. The planar coil PLp1 functions equivalently as the inductive element Lp1 (refer to FIG. 3).

In the planar coil PLp2, the terminal TM11 is electrically connected to a first end of a capacitive element C1, and the terminal TM12 is electrically connected to a first end of a resistive element R1. The planar coil PLp2 functions equivalently as the inductive element Lp2 (refer to FIG. 3).

The planar coil PLn1 and the planar coil PLn2, as viewed in the XY plane, may have a pattern that is linearly symmetrical in the Y direction with respect to an axis of symmetry in the X direction (imaginary line) or in the X direction with respect to an axis of symmetry in the Y direction (imaginary line), relative to the planar coil PLp1 and the planar coil PLp2.

The planar coil PLn1 and the planar coil PLn2 may each has a concentric pattern in the XY plane. The planar coil PLn1 is spaced outward from the planar coil PLn2 in the XY plane. The spacing in each of the X and Y directions can be determined experimentally in advance depending on a coupling coefficient to be achieved between the planar coil PLn1 and the planar coil PLn2.

As viewed in the XY plane, the planar coil PLn1 forms an annular-like shape, extending from a terminal TM3 on the −X side and +Y side and reaching a terminal TM4 on the +X side and +Y side. As viewed in the XY plane, the planar coil PLn2 forms an annular-like shape, extending from a terminal TM13 on the −X side and +Y side and reaching a terminal TM14 on the +X side and +Y side inside the planar coil PLn1. The terminals TM3 and TM4 may be located outward from the terminals TM13 and TM14, respectively, as viewed in the XY plane. In FIG. 8, the patterns of the planar coil PLn1 and the planar coil PLn2 are illustrated as having an approximately octagonal shape, but they may be approximately tetragonal to heptagonal, approximately polygonal with nine or more corners, or approximately circular.

In the planar coil PLn1, the terminal TM3 is electrically connected to an input node inn of the matching circuit 30i, and the terminal TM4 is electrically connected to an output node outn of the matching circuit 30l. The planar coil PLn1 functions equivalently as the inductive element Ln1 (refer to FIG. 3).

In the planar coil PLn2, the terminal TM13 is electrically connected to a second end of the capacitive element C1, and the terminal TM14 is electrically connected to a second end of the resistive element R1. The planar coil PLn2 functions equivalently as the inductive element Ln2 (refer to FIG. 3).

Even the matching circuit 30i as such is capable of maintaining the reflection characteristics of the signal within the allowable range over the wide frequency range FR (refer to FIG. 7).

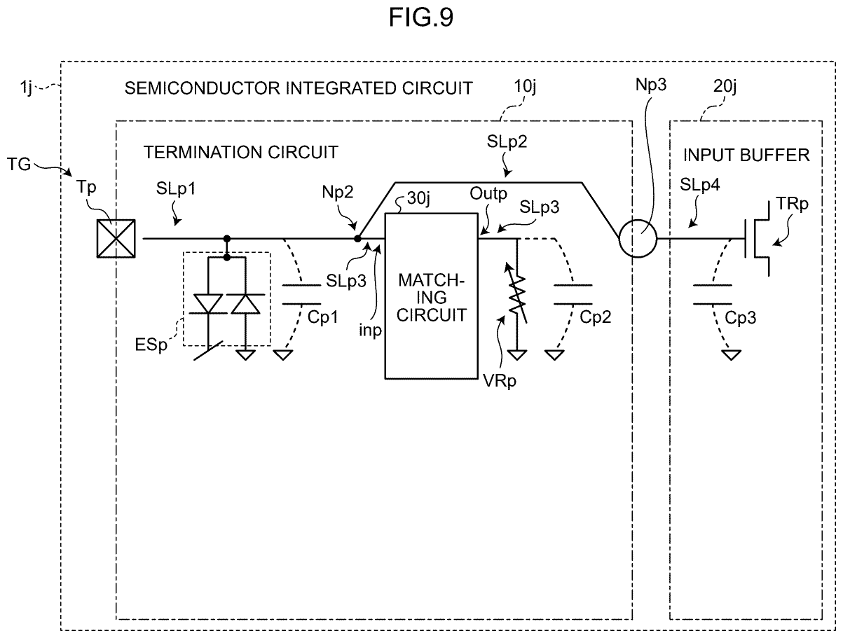

Alternatively, as a second modification of the embodiment, a semiconductor integrated circuit 1j may have a single-ended configuration as illustrated in FIG. 9. The signal received by the semiconductor integrated circuit 1j may be single-ended. FIG. 9 is a circuit diagram illustrating a configuration of the semiconductor integrated circuit 1j according to the second modification of the embodiment.

In a case where the semiconductor integrated circuit 1j has the single-ended configuration, a termination circuit 10j and an input buffer 20j are such that their N-side configurations are omitted, compared to the termination circuit 10 and the input buffer 20 (refer to FIG. 2), respectively.

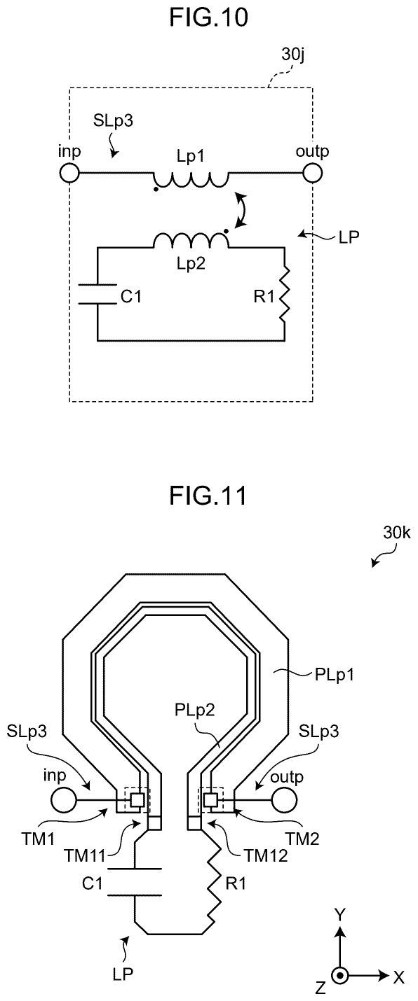

The termination circuit 10j has a matching circuit 30j instead of the matching circuit 30 (refer to FIG. 2). As illustrated in FIG. 10, in the matching circuit 30j, the inductive element Ln2 (refer to FIG. 3) is omitted. In a loop LP, an inductive element Lp2, a resistive element R1, and a capacitive element C1 are inserted so that they are connected in series.

The matching circuit 30j illustrated in FIG. 10 diverts a portion of the energy of the signal transmitted through the inductive element Lp1 to the inductive element Lp2 magnetically coupled to the inductive element Lp1, and the diverted energy is dissipated in the resistive element R1 and the capacitive element C1.

As a result, the matching circuit 30j is capable of maintaining the input resistance value close to the desired resistance value Rt over the wide frequency range (see the solid line in FIG. 5) and maintaining the input reactance value close to the desired reactance value Xt over the wide frequency range (see the solid line in FIG. 6), which is similar to the embodiment.

Thus, even the matching circuit 30j as such makes it possible to keep the signal reflection characteristics within an allowable range over the wide frequency range FR (see the solid line in FIG. 7).

Alternatively, as a third modification of the embodiment, a matching circuit 30k may be implemented as illustrated in FIG. 11. FIG. 11 is a plan view illustrating a configuration of the matching circuit 30k according to the third modification of the embodiment. The matching circuit 30k illustrated in FIG. 11 corresponds to the matching circuit 30j (refer to FIG. 10) and is implemented in a single-ended configuration.

The inductive element Lp1 and the inductive element Lp2 (refer to FIG. 10) may be implemented as a planar coil PLp1 and a planar coil PLp2, respectively, as illustrated in FIG. 11.

The planar coil PLp1 and the planar coil PLp2 may be arranged on substantially the same plane. The configurations of the planar coil PLp1 and the planar coil PLp2 are similar to those in the first modification of the embodiment. Furthermore, the connection relationship between the planar coil PLp1 and the planar coil PLp2 and the surrounding components of the planar coil PLp1 and the planar coil PLp2 are similar to those in the first modification of the embodiment. However, the second end of the capacitive element C1 and the second end of the resistive element R1 are electrically connected, which is different from the first modification of the embodiment. The planar coil PLp1 functions equivalently as the inductive element Lp1 (refer to FIG. 10). The planar coil PLp2 functions equivalently as the inductive element Lp2 (refer to FIG. 10).

Even the matching circuit 30k as such makes it possible to keep the reflection characteristics of the signal within an allowable range in the wide frequency range FR (refer to FIG. 7).

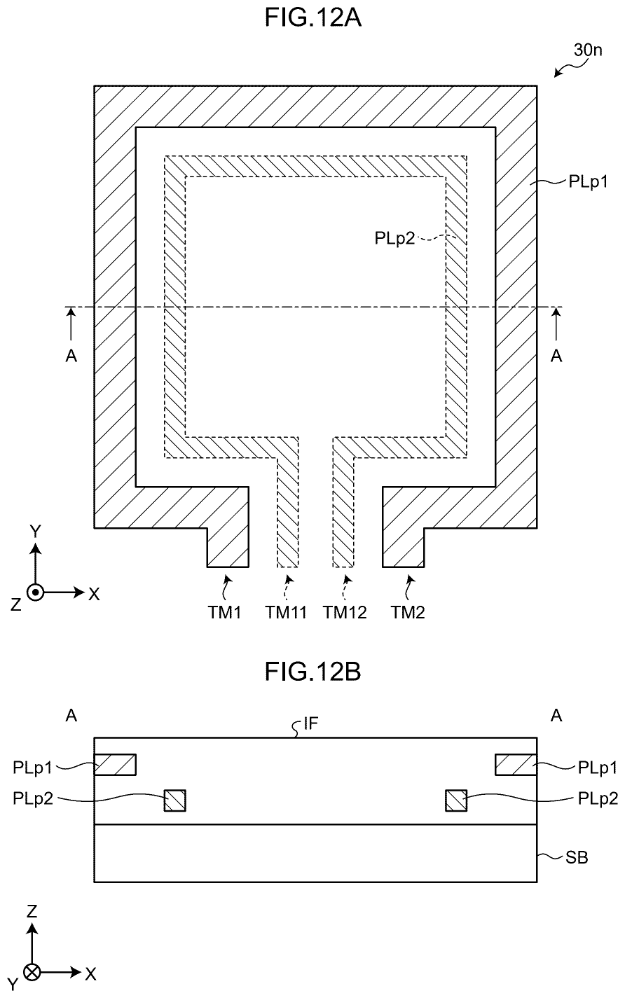

Alternatively, as a fourth modification of the embodiment, a matching circuit 30n may be implemented as illustrated in FIG. 12A and FIG. 12B. FIG. 12A is a plan view and FIG. 12B is a cross-sectional view each illustrating a configuration of the matching circuit 30n according to the fourth modification of the embodiment. FIG. 12A is an XY plan view illustrating the configuration of the matching circuit 30n, and FIG. 12B is a cross-sectional view in the XZ plane illustrating the configuration of the matching circuit 30n, the cross-section being taken along line A-A in FIG. 12A. The matching circuit 30n illustrated in FIGS. 12A and 12B corresponds to the matching circuit 30j (refer to FIG. 10) and is implemented in a single-ended configuration.

The inductive element Lp1 and the inductive element Lp2 (refer to FIG. 10) may be implemented as a planar coil PLp1 and a planar coil PLp2, respectively, as illustrated in FIG. 12A. For simplicity, FIG. 12A selectively illustrates the planar coil PLp1 and the planar coil PLp2 in the matching circuit 30n, and the illustration of the signal line SLp3, the loop LP, the resistive element R1, and the capacitive element C1 are omitted.

The planar coil PLp1 and the planar coil PLp2 may be arranged on a plane with different Z-direction positions (Z-heights) as illustrated in FIG. 12B.

As illustrated in FIG. 12A, the planar coil PLp1 and the planar coil PLp2 may each has a concentric pattern in the XY plane. The planar coil PLp1 is spaced outward from the planar coil PLp2 in the XY plane. The spacing in each of the X, Y, and Z directions can be determined experimentally in advance depending on a coupling coefficient to be achieved between the planar coil PLp1 and the planar coil PLp2.

As viewed in the XY plane, the planar coil PLp1 forms an annular-like shape, extending from a terminal TM1 on the −X side and −Y side and reaching a terminal TM2 on the +X side and −Y side. As viewed in the XY plane, the planar coil PLp2 forms an annular-like shape, extending from a terminal TM11 on the −X side and −Y side and reaching a terminal TM12 on the +X side and −Y side inside the planar coil PLp1. The terminals TM1 and TM2 may be located outward from the terminals TM11 and TM12, respectively, as viewed in the XY plane. In FIG. 12A, the patterns of the planar coils PLp1 and PLp2 are illustrated as being approximately rectangular in shape, but they may be approximately polygonal with five or more corners or approximately circular.

As illustrated in FIG. 12B, the planar coil PLp1 may be arranged as a conductive layer pattern on the +Z side of a substrate SB. The planar coil PLp2 may be arranged as a conductive layer pattern between the substrate SB and the planar coil PLp1 in the Z direction. The substrate SB can be formed of a material that includes a semiconductor such as silicon as its main component. The planar coil PLp1 and the planar coil PLp2 can each be formed of a material that includes a metal such as copper as its main component. An interlayer insulating film IF can be arranged between any two of the substrate SB, the planar coil PLp1, and the planar coil PLp2, thereby providing electrical insulation between them. The interlayer insulating film IF can be formed of an insulator such as silicon oxide.

Although not illustrated, the terminal TM1 in in the planar coil PLp1 is electrically connected to an input node inp of the matching circuit 30n, while the terminal TM2 is electrically connected to an output node outp of the matching circuit 30n. The planar coil PLp1 functions equivalently as the inductive element Lp1 (refer to FIG. 10).

Although not illustrated, the terminal TM11 of the planar coil PLp2 is electrically connected to the first end of the capacitive element C1, while the terminal TM12 is electrically connected to the first end of the resistive element R1. The planar coil PLp2 functions equivalently as the inductive element Lp2 (refer to FIG. 10).

Even the matching circuit 30n as such makes it possible to keep the reflection characteristics of the signal within the allowable range over the wide frequency range FR (refer to FIG. 7).

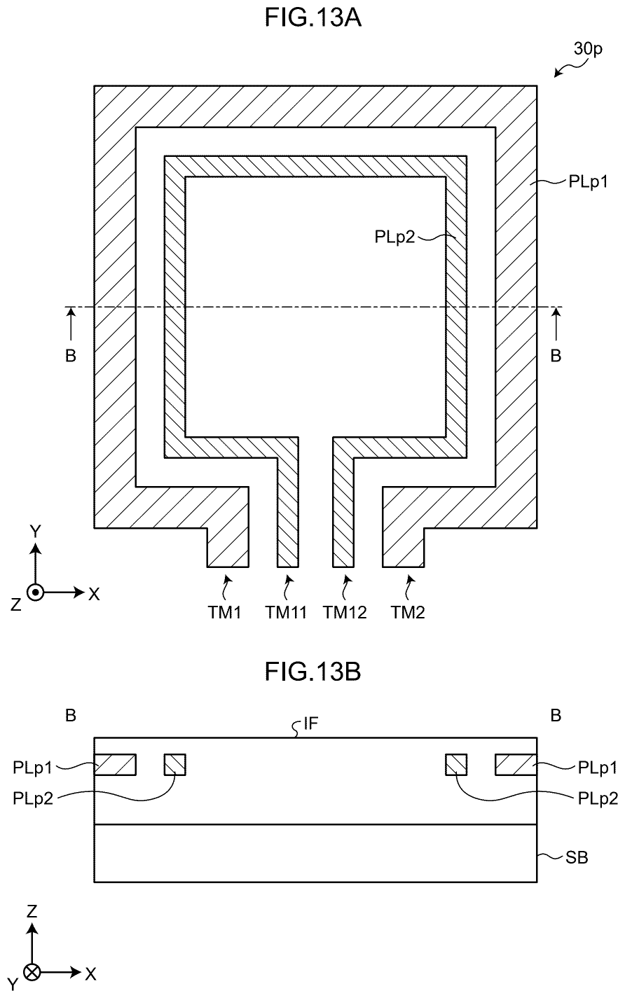

Alternatively, as a fifth modification of the embodiment, a matching circuit 30p may be implemented as illustrated in FIG. 13A and FIG. 13B. FIG. 13A is a plan view and FIG. 13B is a cross-sectional view each illustrating a configuration of the matching circuit 30p according to the fifth modification of the embodiment. FIG. 13A is an XY plan view illustrating the configuration of the matching circuit 30p, and FIG. 13B is an XZ cross-sectional view illustrating the configuration of the matching circuit 30p, the cross-section being taken along line B-B in FIG. 13A. The matching circuit 30p illustrated in FIGS. 13A and 13B corresponds to the matching circuit 30j (refer to FIG. 10) and is implemented in a single-ended configuration.

The inductive element Lp1 and the inductive element Lp2 (refer to FIG. 10) may be implemented as a planar coil PLp1 and a planar coil PLp2, respectively, as illustrated in FIG. 13A. For simplicity, FIG. 13A selectively illustrates the planar coil PLp1 and the planar coil PLp2 in the matching circuit 30p, and the illustrations of the signal line SLp3, the loop LP, the resistive element R1, and the capacitive element C1 are omitted. The configurations of the planar coil PLp1 and the planar coil PLp2 in FIG. 13A are similar to those in the fourth modification of the embodiment. The connection relationship between the planar coil PLp1 and the planar coil PLp2 and the surrounding components of the planar coil PLp1 and the planar coil PLp2 are similar to those in the fourth modification of the embodiment.

The planar coil PLp1 and the planar coil PLp2 may be arranged on a plane with a uniform Z-height, as illustrated in FIG. 13B.

As illustrated in FIG. 13B, the planar coil PLp1 and the planar coil PLp2 may each be arranged as a conductive layer pattern on the +Z side of a substrate SB. The planar coil PLp2 may be arranged at substantially the same position (Z-height) as the Z-height of the planar coil PLp1 with respect to the substrate SB in the Z direction. The materials of the substrate SB, the planar coil PLp1, the planar coil PLp2, and an interlayer insulating film IF may be similar to those in the fourth modification of the embodiment.

Even the matching circuit 30p as such makes it possible to keep the reflection characteristics of the signal within the allowable range over the wide frequency range FR (refer to FIG. 7).

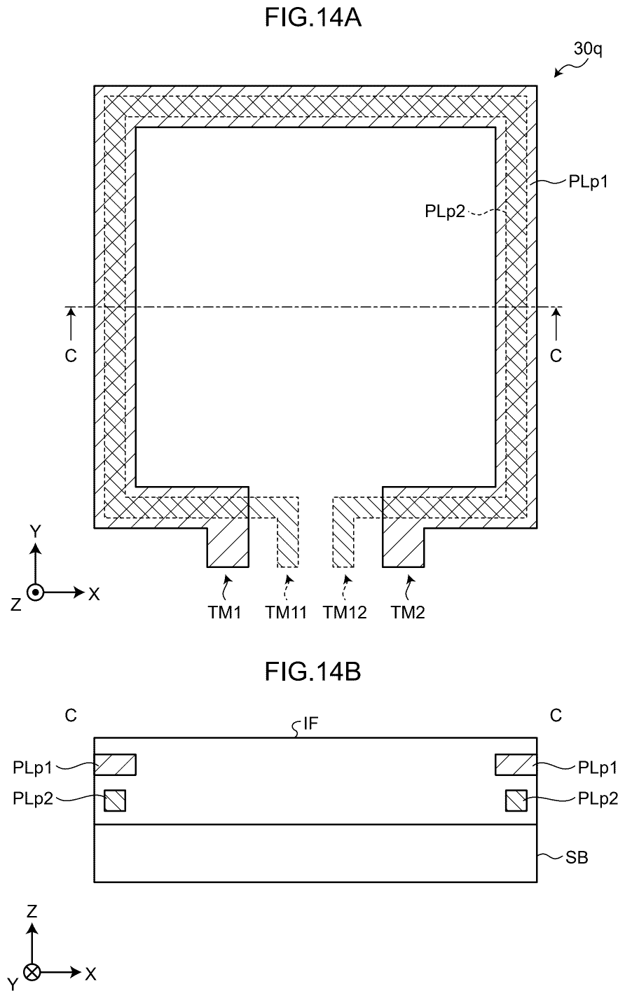

Alternatively, as a sixth modification of the embodiment, a matching circuit 30q may be implemented as illustrated in FIG. 14A and FIG. 14B. FIG. 14A is a plan view and FIG. 14B is a cross-sectional view each illustrating a configuration of the matching circuit 30q according to the sixth modification of the embodiment. FIG. 14A is an XY plan view illustrating the configuration of the matching circuit 30q, and FIG. 14B is an XZ cross-sectional view illustrating the configuration of the matching circuit 30q, the cross-section being taken along line C-C in FIG. 14A. The matching circuit 30q illustrated in FIG. 14A and FIG. 14B corresponds to the matching circuit 30j (refer to FIG. 10) and is implemented in a single-ended configuration.

The inductive element Lp1 and inductive element Lp2 (refer to FIG. 10) may be implemented as a planar coil PLp1 and a planar coil PLp2, respectively, as illustrated in FIG. 14A. For simplicity, FIG. 14A selectively illustrates the planar coil PLp1 and the planar coil PLp2 in the matching circuit 30q, and illustrations of the signal line SLp3, the loop LP, the resistive element R1, and the capacitive element C1 are omitted.

Each of the planar coil PLp1 and the planar coil PLp2 may be arranged on a plane with different Z-heights, as illustrated in FIG. 14B.

As illustrated in FIG. 14A, the planar coil PLp1 and the planar coil PLp2 may each has a concentric pattern in the XY plane. As viewed from the Z direction, a majority of the planar coil PLp1 may overlap the planar coil PLp2. As illustrated in FIG. 14B, the planar coil PLp1 is spaced apart from the planar coil PLp2 in the Z direction (+Z side). The spacing in the Z direction can be experimentally determined in advance depending on a coupling coefficient to be achieved between the planar coil PLp1 and the planar coil PLp2.

As viewed in the XY plane, the planar coil PLp1 forms an annular-like shape, extending from a terminal TM1 on the −X side and −Y side and reaching a terminal TM2 on the +X side and −Y side. As viewed in the XY plane, the planar coil PLp2 forms an annular-like shape, extending from a terminal TM11 on the −X side and −Y side along the planar coil PLp1 and reaching a terminal TM12 on the +X side and −Y side. The terminals TM1 and TM2 may be located outward from the terminals TM11 and TM12, respectively, in the X direction. In FIG. 14A, the patterns of the planar coil PLp1 and the planar coil PLp2 are illustrated as having an approximately rectangular shape, but they may be approximately polygonal with five or more corners or approximately circular.

As illustrated in FIG. 14B, the planar coil PLp1 may be arranged as a conductive layer pattern on the +Z side of a substrate SB. The planar coil PLp2 may be arranged as a conductive layer pattern between the substrate SB and the planar coil PLp1 in the Z direction. The materials of the substrate SB, the planar coil PLp1, the planar coil PLp2, and an interlayer insulating film IF may be similar to those of the fourth modification of the embodiment.

Although not illustrated, the terminal TM1 of the planar coil PLp1 is electrically connected to an input node inp of the matching circuit 30q, while the terminal TM2 is electrically connected to an output node outp of the matching circuit 30q. The planar coil PLp1 functions equivalently as the inductive element Lp1 (refer to FIG. 10).

Although not illustrated, the terminal TM11 of the planar coil PLp2 is electrically connected to the first end of the capacitive element C1, while the terminal TM12 is electrically connected to the first end of the resistive element R1. The planar coil PLp2 functions equivalently as the inductive element Lp2 (refer to FIG. 10).

Even the matching circuit 30q as such makes it possible to keep the reflection characteristics of the signal within the allowable range over the wide frequency range FR (refer to FIG. 7).

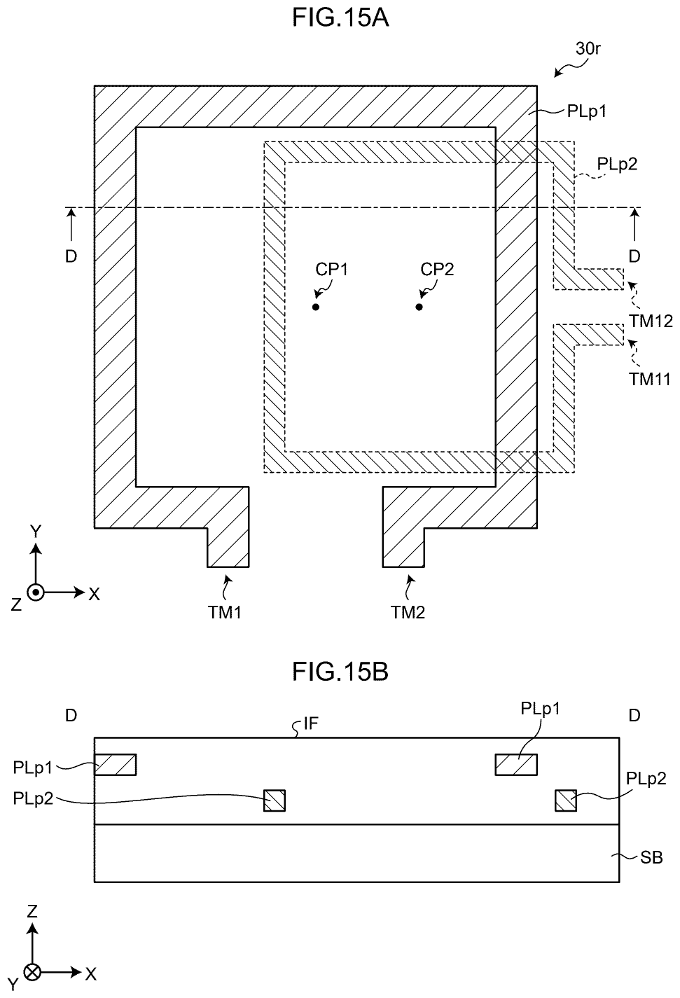

Alternatively, as a seventh modification of the embodiment, a matching circuit 30r may be implemented as illustrated in FIG. 15A and FIG. 15B. FIG. 15A is a plan view and FIG. 15B is a cross-sectional view each illustrating a configuration of the matching circuit 30r according to the seventh modification of the embodiment. FIG. 15A is an XY plan view illustrating the configuration of the matching circuit 30r, and FIG. 15B is an XZ cross-sectional view illustrating the configuration of the matching circuit 30r, the cross-section being taken along line D-D in FIG. 15A. The matching circuit 30r illustrated in FIG. 15A and FIG. 15B corresponds to the matching circuit 30j (refer to FIG. 10) and is implemented in a single-ended configuration.

The inductive element Lp1 and the inductive element Lp2 (refer to FIG. 10) may be implemented as a planar coil PLp1 and a planar coil PLp2, respectively, as illustrated in FIG. 15A. For simplicity, FIG. 15A selectively illustrates the planar coil PLp1 and the planar coil PLp2 in the matching circuit 30r, and the illustrations of the signal line SLp3, the loop LP, the resistive element R1, and the capacitive element C1 are omitted.

Each of the planar coil PLp1 and the planar coil PLp2 may be arranged on a plane with different Z-heights, as illustrated in FIG. 15B.

The planar coil PLp1 and the planar coil PLp2 illustrated in FIG. 15A may have patterns in which their centers are shifted relative to each other in the X direction as viewed in the XY plane. FIG. 15A illustrates a configuration in which a center CP2 of the planar coil PLp2 is shifted to the +X side relative to a center CP1 of the planar coil PLp1. As viewed in perspective from the Z direction, a portion of the planar coil PLp1 may overlap the planar coil PLp2. FIG. 15A illustrates a configuration in which one portion of the planar coil PLp2 is located inside the planar coil PLp1, and the other portion of the planar coil PLp2 is located outward from the planar coil PLp1 in the XY plane as viewed in perspective from the Z direction.

As illustrated in FIG. 15B, the planar coil PLp1 is spaced apart from the planar coil PLp2 in the Z direction (+Z side). The shift amounts of the centers and the spacing in the Z direction of the planar coil PLp1 and the planar coil PLp2 can be experimentally determined in advance depending on a coupling coefficient to be achieved between the planar coil PLp1 and the planar coil PLp2.

As viewed in the XY plane, the planar coil PLp1 forms an annular-like shape, extending from a terminal TM1 on the −X side and −Y side and reaching a terminal TM2 on the +X side and −Y side. As viewed in the XY plane, the planar coil PLp2 forms an annular-like shape, extending from a terminal TM11 on the +X side and −Y side and reaching a terminal TM12 on the +X side and +Y side along a trajectory that enters the inside of the planar coil PLp1 from the +X side and then exits back to the outside of the +X side of the planar coil PLp1. The terminals TM1 and TM2 may be located on the −Y side of the planar coil PLp1, and the terminals TM11 and TM12 may be located on the +X side of the planar coil PLp2. In FIG. 15A, the patterns of the planar coil PLp1 and the planar coil PLp2 are illustrated as having an approximately rectangular shape, but the patterns may be approximately polygonal with five or more corners or approximately circular.

As illustrated in FIG. 15B, the planar coil PLp1 may be arranged as a conductive layer pattern on the +Z side of a substrate SB. The planar coil PLp2 may be arranged as a conductive layer pattern between the substrate SB and the planar coil PLp1 in the Z direction. The materials of the substrate SB, the planar coil PLp1, the planar coil PLp2, and an interlayer insulating film IF may be similar to those in the fourth modification of the embodiment.

Although not illustrated, the terminal TM1 of the planar coil PLp1 is electrically connected to an input node inp of the matching circuit 30r, while the terminal TM2 is electrically connected to an output node outp of the matching circuit 30r. The planar coil PLp1 functions equivalently as the inductive element Lp1 (refer to FIG. 10).

Although not illustrated, the terminal TM11 of the planar coil PLp2 is electrically connected to the first end of the capacitive element C1, while the terminal TM12 is electrically connected to the first end of the resistive element R1. The planar coil PLp2 functions equivalently as the inductive element Lp2 (refer to FIG. 10).

Even the matching circuit 30r as such makes it possible to keep the signal reflection characteristics within the allowable range over the wide frequency range FR (refer to FIG. 7).

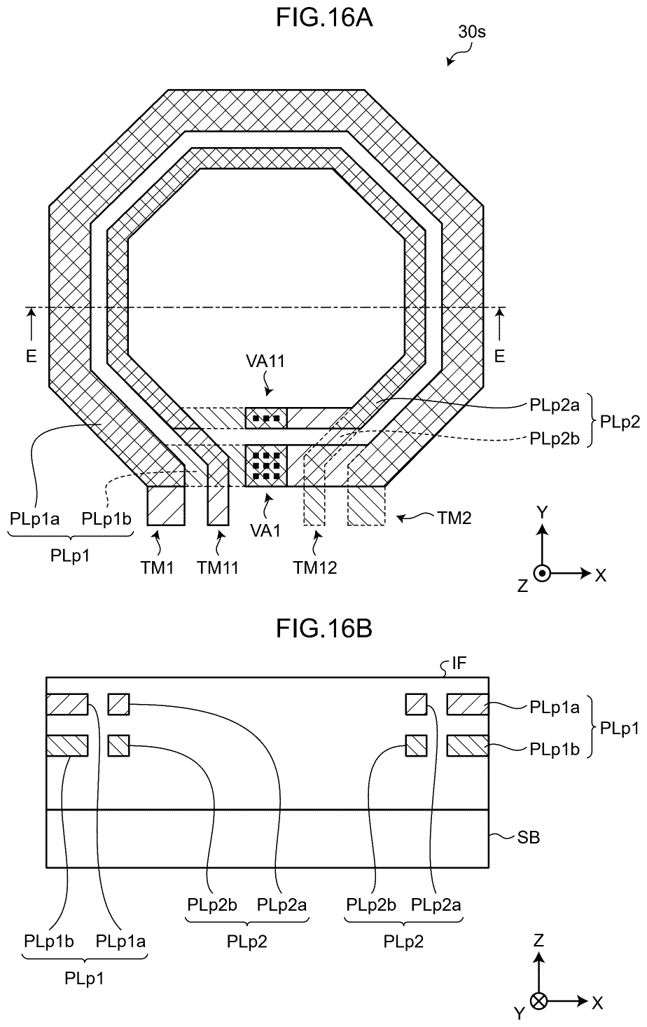

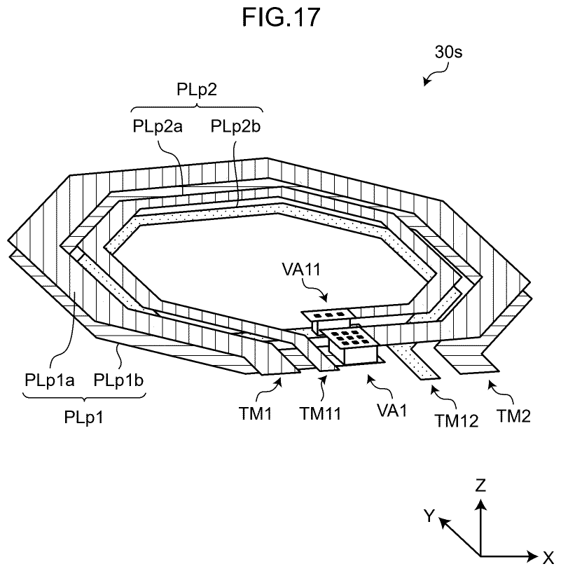

Alternatively, as an eighth modification of the embodiment, a matching circuit 30s may be implemented as illustrated in FIGS. 16A, 16B, and 17. FIG. 16A is a plan view and FIG. 16B is a cross-sectional view each illustrating a configuration of the matching circuit 30s according to the eighth modification of the embodiment. FIG. 17 is a perspective view illustrating the configuration of the matching circuit 30s according to the eighth modification of the embodiment. FIG. 16A is an XY plan view illustrating the configuration of the matching circuit 30s, and FIG. 16B is an XZ cross-sectional view illustrating the configuration of the matching circuit 30s, the cross-section being taken along line E-E in FIG. 16A. The matching circuit 30s illustrated in FIGS. 16A and 16B corresponds to the matching circuit 30j (refer to FIG. 10) and is implemented in a single-ended configuration.

The inductive element Lp1 and the inductive element Lp2 (refer to FIG. 10) may be implemented as a planar coil PLp1 and a planar coil PLp2, respectively, as illustrated in FIG. 16A. For simplicity, FIG. 16A selectively illustrates the planar coil PLp1 and the planar coil PLp2 in the matching circuit 30s, and the illustrations of the signal line SLp3, the loop LP, the resistive element R1, and the capacitive element C1 are omitted.

The planar coil PLp1 and the planar coil PLp2 may be, as illustrated in FIG. 16B, arranged across multiple planes with different Z-heights.

As illustrated in FIG. 16A, the planar coil PLp1 and the planar coil PLp2 may each has a concentric pattern in the XY plane. The planar coil PLp1 is spaced outward from the planar coil PLp2 in the XY plane. The spacing in each of the X and Y directions can be determined experimentally in advance depending on a coupling coefficient to be achieved between the planar coil PLp1 and the planar coil PLp2. In FIG. 16A, the patterns of the planar coil PLp1 and the planar coil PLp2 are illustrated as having approximately octagonal, but the patterns may be approximately tetragonal to heptagonal, approximately polygonal with nine or more corners, or approximately circular.

As illustrated in FIGS. 16B and 17, the planar coil PLp1 may be arranged as a multilayer wiring structure on the +Z side of a substrate SB. The planar coil PLp1 includes multiple conductive layers PLpla and PLplb with different Z-heights and a via VAI that connects the multiple conductive layers PLpla and PLplb in the Z direction. The planar coil PLp2 may be arranged as a multilayer wiring structure on the +Z side of the substrate SB. The planar coil PLp2 includes multiple conductive layers PLp2a and PLp2b with different Z-heights and a via VA11 that connects the multiple conductive layers PLp2a and PLp2b in the Z direction. The substrate SB may be formed of a material that includes a semiconductor such as silicon as its main component. The conductive layers PLpla and PLplb and the conductive layers PLp2a and PLp2b may each be formed of a material that includes a metal such as copper as its main component. The via VAI and the via VA11 may each be formed of a material that includes a metal such as tungsten as its main component. An interlayer insulating film IF can be arranged between any two of the substrate SB, the conductive layers PLpla and PLplb, and the conductive layers PLp2a and PLp2b, thereby providing electrical insulation from one another. The interlayer insulating film IF can be made of an insulating material such as silicon oxide.

As illustrated in FIGS. 16A and 17, in the planar coil PLp1, the conductive layer PLpla forms an annular-like shape, extending from a terminal TM1 on the −X side and −Y side and reaching the via VAI at a termination portion on the +X side of the terminal TM1. The via VAI extends in the −Z direction from the termination portion of the conductive layer PLpla to an initiation portion of the conductive layer PLplb. The conductive layer PLplb forms an annular-like shape, extending from the initiation portion and reaching a terminal TM2 on the +X side and −Y side.

In the planar coil PLp2, the conductive layer PLp2a forms an annular-like shape, extending from a terminal TM11 on the −X side and −Y side and reaching the via VA11 at a termination portion on the +X side of the terminal TM11. The via VA11 extends in the −Z direction from the termination portion of the conductive layer PLp2a and reaches an initiation portion of the conductive layer PLp2b. The conductive layer PLp2b forms an annular-like shape, extending from the initiation portion and reaching a terminal TM12 on the +X side and −Y side. The terminals TM1 and TM2 may be located outward from the terminals TM11 and TM12, respectively, as viewed in the XY plane.

Although not illustrated, in the planar coil PLp1, the terminal TM1 is electrically connected to an input node inp of the matching circuit 30s, while the terminal TM2 is electrically connected to an output node outp of the matching circuit 30s. The planar coil PLp1 functions equivalently as the inductive element Lp1 (refer to FIG. 10).

Although not illustrated, in the planar coil PLp2, the terminal TM11 is electrically connected to the first end of the capacitive element C1, while the terminal TM12 is electrically connected to the first end of the resistive element R1. The planar coil PLp2 functions equivalently as the inductive element Lp2 (refer to FIG. 10).

Even the matching circuit 30s as such makes it possible to keep the reflection characteristics of the signal within the allowable range over the wide frequency range FR (refer to FIG. 7).

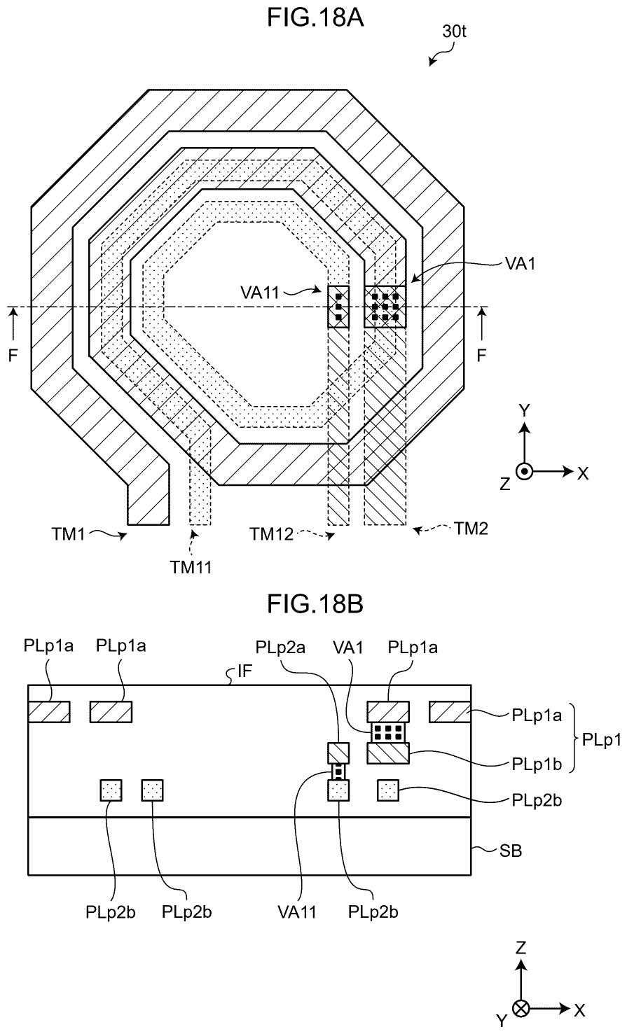

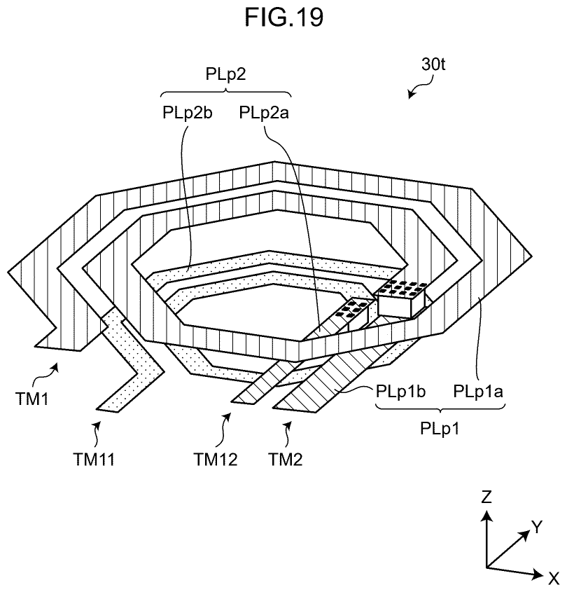

Alternatively, as a ninth modification of the embodiment, a matching circuit 30t may be implemented as illustrated in FIG. 18A, FIG. 18B, and FIG. 19. FIG. 18A is a plan view and FIG. 18B is a cross-sectional view each illustrating a configuration of the matching circuit 30t according to the ninth modification of the embodiment. FIG. 19 is a perspective view illustrating the configuration of the matching circuit 30t according to the eighth modification of the embodiment. FIG. 18A is an XY plan view illustrating the configuration of the matching circuit 30t, and FIG. 18B is an XZ cross-sectional view illustrating the configuration of the matching circuit 30t, the cross-section being taken along line F-F in FIG. 18A. The matching circuit 30t illustrated in FIG. 18A and FIG. 18B corresponds to the matching circuit 30j (refer to FIG. 10) and is implemented in a single-ended configuration.

The inductive element Lp1 and the inductive element Lp2 (refer to FIG. 10) may be implemented as a planar coil PLp1 and a planar coil PLp2, respectively, as illustrated in FIG. 18A. For simplicity, FIG. 18A selectively illustrates the planar coil PLp1 and the planar coil PLp2 in the matching circuit 30t, and the illustrations of the signal line SLp3, the loop LP, the resistive element R1, and the capacitive element C1 are omitted.

As illustrated in FIG. 18B, the planar coil PLp1 and the planar coil PLp2 may be arranged across multiple planes with different Z-heights. Multiple planes on which the planar coil PLp1 is arranged may overlap partially with or differ partially from multiple planes on which the planar coil PLp2 is arranged.

As illustrated in FIG. 18A, the planar coil PLp1 and the planar coil PLp2 may each has a concentric pattern in the XY plane. In the XY plane, the planar coil PLp1 is spaced outward from the planar coil PLp2 and is spaced in the Z direction. The spacing in each of the X, Y, and Z directions can be determined experimentally in advance depending on a coupling coefficient to be achieved between the planar coil PLp1 and the planar coil PLp2. In FIG. 18A, the patterns of the planar coil PLp1 and the planar coil PLp2 are illustrated as having an approximately octagonal shape, but the patterns may be approximately tetragonal to heptagonal, approximately polygonal with nine or more corners, or approximately circular.

As illustrated in FIG. 18B and FIG. 19, the planar coil PLp1 may be arranged as a multilayer wiring structure on the +Z side of a substrate SB. The planar coil PLp1 includes multiple conductive layers PLpla and PLplb having different Z-heights and a via VAI connecting the multiple conductive layers PLpla and PLplb in the Z direction. The planar coil PLp2 may be arranged as a multilayer wiring structure on the +Z side of the substrate SB. The planar coil PLp2 includes multiple conductive layers PLp2a and PLp2b having different Z-heights and a via VA11 that connects the multiple conductive layers PLp2a and PLp2b in the Z direction. The conductive layer PLplb of the planar coil PLp1 and the conductive layer PLp2a of the planar coil PLp2 may be substantially the same Z-height. The conductive layer PLpla of the planar coil PLp1 and the conductive layer PLp2b of the planar coil PLp2 may have different Z-heights. The conductive layer PLpla may have a higher Z-height than the conductive layer PLplb and the conductive layer PLp2a, and the conductive layer PLp2b may have a lower Z-height than the conductive layer PLplb and the conductive layer PLp2a.

The materials of the substrate SB, the planar coil PLp1, the planar coil PLp2, and an interlayer insulating film IF may be similar to those in the eighth modification of the embodiment.

As illustrated in FIGS. 18A and 19, in the planar coil PLp1, the conductive layer PLpla forms a spiral shape, extending from a terminal TM1 on the −X side, −Y side, and +Z side and reaching the via VAI at a termination portion thereof. The via VAI extends from the termination portion of the conductive layer PLpla in the −Z direction and reaches an initiation portion of the conductive layer PLplb. The conductive layer PLplb extends linearly from the initiation portion in the −Y direction and reaches a terminal TM2 on the +X and −Y sides.

In the planar coil PLp2, the conductive layer PLp2b forms a spiral shape, extending from a terminal TM11 on the −X, −Y, and −Z sides and reaching the via VA11 at a termination portion thereof. The via VA11 extends from the termination portion of the conductive layer PLp2b in the +Z direction and reaches an initiation portion of the conductive layer PLp2a. The conductive layer PLp2a extends linearly from the initiation portion in the −Y direction and reaches the terminal TM12 on the +X and −Y sides. The terminals TM1 and TM2 may be located outward from the terminals TM11 and TM12, respectively, as viewed in the XY plane.

The connection relationship between the planar coil PLp1 and planar coil PLp2 and the surrounding components of the planar coil PLp1 and planar coil PLp2 are similar to those in the eighth modification of the embodiment. The planar coil PLp1 functions equivalently as an inductive element Lp1 (refer to FIG. 10). The planar coil PLp2 functions equivalently as the inductive element Lp2 (refer to FIG. 10).

Even the matching circuit 30t as such makes it possible to keep the reflection characteristics of the signal within the allowable range over the wide frequency range FR (refer to FIG. 7).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor integrated circuit comprising:
a first inductive element provided in a first signal line; and
a second inductive element provided in a loop and magnetically coupled to the first inductive element, the loop being arranged apart from the first signal line,
wherein the first signal line has signal terminals arranged at both ends, and
the loop is configured to be devoid of the signal terminal.

2. The semiconductor integrated circuit according to claim 1, further comprising:
a resistive element provided in the loop and connected in series with the second inductive element; and
a capacitive element provided in the loop and connected in series with the second inductive element and the resistive element.

3. The semiconductor integrated circuit according to claim 1, further comprising:
a third inductive element provided in a second signal line; and
a fourth inductive element provided in the loop and magnetically coupled to the third inductive element, the loop being arranged apart from the first signal line and the second signal line.

4. The semiconductor integrated circuit according to claim 3, further comprising:
a resistive element provided in the loop and connected in series with the second inductive element; and
a capacitive element provided in the loop and connected in series with the second inductive element and the resistive element.

5. The semiconductor integrated circuit according to claim 1,
wherein the first inductive element includes a first planar coil,
the second inductive element includes a second planar coil, and
the first planar coil and the second planar coil are concentric in a plan view.

6. The semiconductor integrated circuit according to claim 5,
wherein the first planar coil and the second planar coil do not overlap each other in the plan view.

7. The semiconductor integrated circuit according to claim 5,
wherein the first planar coil and the second planar coil overlap each other in the plan view.

8. The semiconductor integrated circuit according to claim 1,
wherein the first inductive element includes a first planar coil,
the second inductive element includes a second planar coil, and
each of the first planar coil and the second planar coil has a center shifted relative to each other in a plan view.

9. The semiconductor integrated circuit according to claim 1,
wherein the first inductive element includes a first planar coil,
the second inductive element includes a second planar coil,
the first planar coil and the second planar coil are each arranged above a substrate, and
the first planar coil and the second planar coil are each positioned at substantially an equal height above the substrate.

10. The semiconductor integrated circuit according to claim 9,
wherein the first planar coil and the second planar coil are concentric in a plan view.

11. The semiconductor integrated circuit according to claim 9,
wherein the first planar coil and the second planar coil do not overlap each other in a plan view.

12. The semiconductor integrated circuit according to claim 1,
wherein the first inductive element includes a first planar coil,
the second inductive element includes a second planar coil,
the first planar coil and the second planar coil are each arranged above a substrate, and
the first planar coil and the second planar coil are positioned at different heights above the substrate.

13. The semiconductor integrated circuit according to claim 12,
wherein the first planar coil and the second planar coil are concentric in a plan view.

14. The semiconductor integrated circuit according to claim 13,
wherein the first planar coil and the second planar coil do not overlap each other in the plan view.

15. The semiconductor integrated circuit according to claim 13,
wherein the first planar coil and the second planar coil overlap each other in the plan view.

16. The semiconductor integrated circuit according to claim 12,
wherein each of the first planar coil and the second planar coil has a center shifted relative to each other in a plan view.

17. The semiconductor integrated circuit according to claim 1,
wherein the first inductive element includes a first planar coil,
the second inductive element includes a second planar coil,
the first planar coil and the second planar coil are each arranged above a substrate, and
the first planar coil and the second planar coil each include multiple conductive layers and a via, the conductive layers having different heights from the substrate, the via being configured to connect the multiple conductive layers.

18. A semiconductor integrated circuit comprising:
a first inductive element provided in a first signal line;
a second inductive element provided in a loop and magnetically coupled to the first inductive element, the loop being arranged apart from the first signal line;
a resistive element provided in the loop and connected in series with the second inductive element; and
a capacitive element provided in the loop and connected in series with the second inductive element and the resistive element.

19. The semiconductor integrated circuit according to claim 18, further comprising:
a third inductive element provided in a second signal line; and
a fourth inductive element provided in the loop and magnetically coupled to the third inductive element, the loop being arranged apart from the first signal line and the second signal line.

20. A receiving device comprising:
the semiconductor integrated circuit according to claim 1, the semiconductor integrated circuit being connectable to a communication line; and
a processing circuit connected to the semiconductor integrated circuit and configured to be capable of processing a signal output from the semiconductor integrated circuit.
